(19) United States
(12) Patent Application Publication
(10) Pub. No.: US 2010/0239401 A1
(43) Pub. Date: Sep. 23, 2010

(54) CARRIER TAPE FEEDER FOR CHIP MOUNTER

(76) Inventor: Kwang-Sik Kim, Yongin-City (KR)

Correspondence Address: Robert L. Stearns, Esq.;DICKINSON WRIGHT PLLC, Suite 2000, 38525 Woodward Avenue, Bloomfield Hills, MI, 48304-2970, US

(21) Appl. No.: 12/719,980

(22) Filed: Mar. 9, 2010

(30) Foreign Application Priority Data
Mar. 9, 2009 (KR) 10 2009 0019757
Feb. 5, 2010 (KR) 10 2010 0010848

(51) Int. Cl. H05K 13/02

(52) U.S. Cl. 414/412

(57) ABSTRACT

There is provided a carrier tape feeder for a chip mounter, which consecutively and automatically supplies a carrier tape which retains small electronic components at regular intervals and is sealed by a vinyl cover to the chip mounter to mount the components onto a printed circuit board.

To consecutively and automatically supply components retained in a carrier tape to a chip mounter, the carrier tape feeder for the chip mounter comprises: a pickup section to separate a part of a vinyl cover from a base tape of the carrier tape so that the components retained in the base tape can be picked up, wherein the pickup section connected to an end of a tape feeder body comprises: a tape guide to secure a path of the carrier tape from which the part of the vinyl cover is separated longitudinally and to discharge the base tape and the vinyl cover together in the same direction simultaneously, wherein the tape guide comprises: a blade to separate longitudinally the vinyl cover from the base tape of the carrier tape being fed; and a vinyl cover guider to guide the separated vinyl cover.

### CROSS-REFERENCE TO RELATED APPLICATION

This application claims the benefit of Korean Patent Application Nos. 10-2009-0019757 filed on Mar. 9, 2009 and 10-2010-0010848 filed on Feb. 5, 2010, the disclosure of which is hereby incorporated herein by reference in its entirety.

### BACKGROUND OF THE INVENTION

1. Field of the Invention

The present invention relates to a carrier tape feeder for a chip mounter, and more particularly, to a carrier tape feeder for a chip mounter, which consecutively and automatically feeds a carrier tape which retains small electronic components, such as semiconductor chips, at regular intervals and seals the components with a vinyl cover, onto a chip mounter for mounting the components onto a printed circuit board.

2. Description of the Related Art

A chip mounter is an apparatus to pick up small components fed by a feeder by vacuum suction using a nozzle of a head, and to mount, at high-speed and with high-precision, the components onto a printed circuit board where a mounting position for each component is predetermined.

Recent electronic products/devices have been developed for high-performance and small-size. Accordingly, components of high-density are required to be mounted in those electronic products/devices. As the technology for mounting components, a surface mounted technology (SMT) method is mainly used, instead of a conventional through-hole method. The SMT is a method for directly mounting small and high-density components onto the surface of a printed circuit board. A tape roll form, a tray form and a stick form are classified according to the forms of feeding components to a chip mounter. Feeders are classified into a tape feeder, a tray feeder and a stick feeder according to the forms of retaining components to be fed. Among these, a tape feeder is widely used because it can feed components at high-speed and in great quantities. The tape feeder uses a carrier tape which retains small electronic components at regular intervals and seals them by a vinyl cover.

After a carrier tape retains small electronic components, such as semiconductor chips, in receiving spaces formed to be spaced apart from each other, at a pitch of a regular interval, in a base tape of a paper material, it seals the retained components through a taping process using a vinyl cover. In a product of a carrier tape, the carrier tape is wound about a reel and it includes tape transfer holes formed at predetermined intervals, in a length direction of the carrier tape, at one side of the carrier tape. The tape feeder to be mounted onto the chip mounter moves the carrier tape at a predetermined pitch by locking the transfer holes of the carrier tape and separates the vinyl cover from the base tape. As the vinyl cover is separated from the base tape, the receiving spaces are exposed so that the electronic components retained in the receiving spaces are picked up by the suction nozzle of the chip mounter, to be mounted on the board.

In a conventional tape feeder, after the vinyl cover is separated from the base tape of the carrier tape, the base tape is discharged toward the front of the tape feeder and the vinyl cover is discharged toward the back of the tape feeder. Therefore, the vinyl cover gets tangled around a vinyl cover discharge unit. Then, static electricity is generated and therefore the attraction phenomenon of vinyl occurs. This changes the pitch of the carrier tape, thereby making it difficult to accurately feed the components. Further, a plurality of the tape feeders is mounted onto the chip mounter. In this case, when the vinyl cover discharged by being separated from the carrier tape in each tape feeder gets tangled together, static electricity is generated to cause many problems in the work for mounting components. Consequently, there are caused serious problems of stopping the work to mount the components or producing defective products.

When the base tape of the carrier tape is transferred in a normally unfold and flat state, there is no problem. However, when a thickness of an electronic component retained in the carrier tape is thick or when the base tape is transferred in a uneven and bent state, along the length direction even though the thickness of the electronic component is not thick, the electronic components retained in the carrier tape cannot be consecutively and automatically fed to the chip mounter. Moreover, since the vinyl cover is affixed to the base tape, even though the carrier tape is fed in the normal state, it is difficult to separate the vinyl cover from the base tape at a front end of the carrier tape.

### SUMMARY OF THE INVENTION

Therefore, it is an object of the present invention to provide a carrier tape feeder for a chip mounter, which basically prevents the problems caused when a discharged vinyl cover gets tangled or comes into contact together after the vinyl cover is separated from a base tape of a carrier tape and components retained in the carrier tape are picked up, so that the vinyl cover is smoothly discharged.

It is another object of the present invention to provide a carrier tape feeder for a chip mounter, which normally consecutively and automatically feeds electronic components retained in receiving spaces of a carrier tape even though the carrier tape is transferred in an abnormally deformed state not in a straight flat state, and which easily separates a vinyl cover affixed to a base tape at a front end of the carrier tape.

In accordance with an embodiment of the present invention, there is provided a carrier tape feeder for a chip mounter, which consecutively and automatically feeds components retained in a carrier tape to the chip mounter, comprising: a pickup section to separate a part of a vinyl cover from a base tape of the carrier tape so that the components retained in the base tape can be picked up, wherein the pickup section connected to an end of a tape feeder body comprises: a tape guide to secure a path of the carrier tape from which the part of the vinyl cover is separated longitudinally and to discharge the base tape and the vinyl cover together in the same direction simultaneously, wherein the tape guide comprises: a blade to separate longitudinally the vinyl cover from the base tape of the carrier tape being fed; and a vinyl cover guider to guide the separated vinyl cover.

Preferably, the carrier tape feeder may further comprises: a tape supplying section to supply the carrier tape transferred from a reel wound with the carrier tape to the pickup section, wherein the tape supplying section comprises: a guide member to be positioned at an upper position of the tape supplying section and to secure and pass the carrier tape supplied from a tape storage section; a guide cover to be connected with the guide member; and a first driving member to generate a driving force to transfer the carrier tape.

Preferably, the tape supplying section may further comprise: guide pins to be positioned at both sides of a front end and a back end of the tape supplying section and to connect the guide member and the guide cover; guide grooves each in a shape of a vertically long opening formed at the guide cover so that the connected guide pin is vertically movable; and an elastic member to elastically support the guide cover to the guide member.

Preferably, the tape guide may comprise: a blade to separate the vinyl cover from the base tape of the supplied carrier tape; a hook with a front end bent in a ‘┐’ shape to catch a front end of the carrier tape and thus to easily separate the vinyl cover from the base tape; a leaf spring to be installed to be positioned under the blade and the front end of the hook and to support the carrier tape; and a vinyl cover guider to guide the vinyl cover separated by the blade.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a sectional view illustrating a tape feeder according to the present invention;

FIG. 2 illustrates a tape supplying section in which a carrier tape is not interposed between a guide member and a guide cover;

FIG. 3 illustrates the tape supplying section in which a carrier tape is interposed between the guide member and the guide cover;

FIG. 4 is a view for explaining the connection relationship of the guide member and the guide cover in the tape supplying section;

FIG. 5 illustrates a pickup section in the tape feeder according to a first embodiment of the present invention;

FIG. 6 illustrates that a vinyl cover is unidirectionally separated from a base tape by a blade of a tape guide, to be discharged and folded;

FIGS. 7A and 7B are views for explaining that the vinyl cover is unidirectionally separated from the base tape by the blade of the tape guide;

FIG. 8 illustrates that the vinyl cover is bidirectionally separated from the base tape by the blade of the tape guide, to be discharged and folded;

FIG. 9 is a perspective view illustrating a back side of the tape guide shown in FIG. 8;

FIG. 10 is a view for explaining that the vinyl cover is bidirectionally separated from the base tape by the blade;

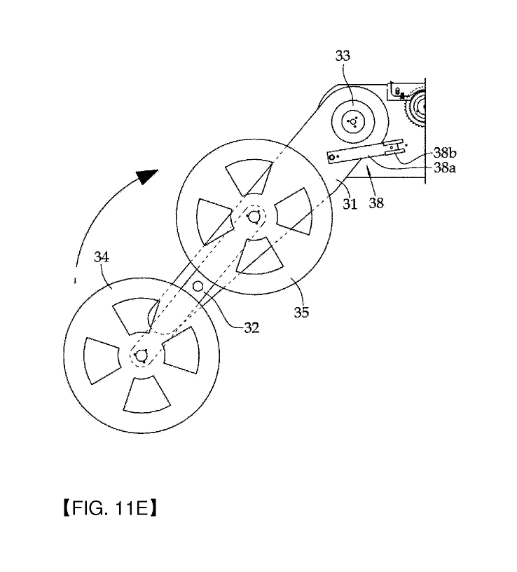

FIGS. 11A through 11E are views for explaining a process of replacing a reel in a tape storage section;

FIG. 12 illustrates a pickup section in the tape feeder according to a second embodiment of the present invention;

FIG. 13 is a perspective view and plan view illustrating a tape guide in the pickup section according to the second embodiment;

FIG. 14 is a sectional view illustrating a hook attached to the tape guide;

FIG. 15 is a sectional view illustrating various examples of a leaf spring.

### DETAILED DESCRIPTION OF THE PREFERRED EMBODIMENT

The present invention will now be described more fully hereinafter with reference to the accompanying drawings, in which preferred embodiments of the invention are shown so that those of ordinary skill in the art can easily carry out the present invention.

It will be further understood that, although the terms, “first”, “second”, etc., may be used herein to describe various elements, these elements should not be limited by these terms. These terms are only used to distinguish one element from another, not to indicate relative importance or purposes. As used herein, the singular forms “a”, “an” and “the” are intended to include the plural forms as well, unless the context clearly indicates otherwise.

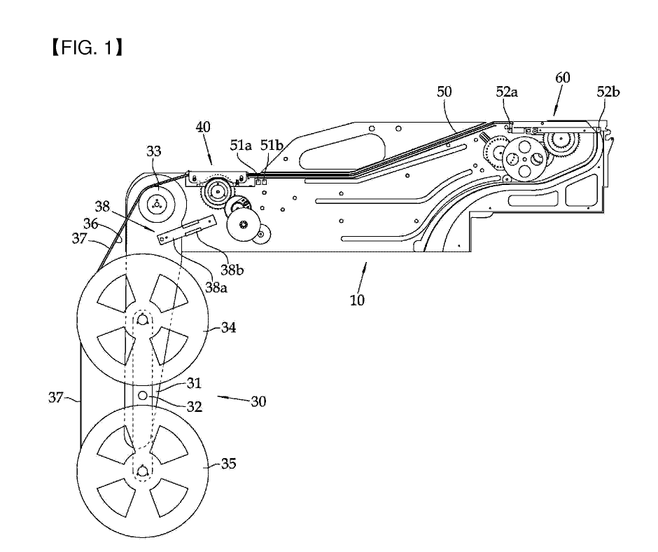

The present invention relates to a carrier tape feeder which is an apparatus for automatically feeding electronic components in a chip mounter for mounting very small electronic components onto a printed circuit board (hereinafter, referred to as the ‘tape feeder’). As illustrated in FIG. 1, the tape feeder generally comprises: a tape feeder body 10, a tape storage section 30, a tape supplying section 40, a tape guide section 50 to guide the movement of a carrier tape 20 supplied from the tape supplying section 40, and a pickup section 60 to discharge a base tape and a vinyl cover together in the same direction simultaneously after electronic components retained in the carrier tape 20 are picked up from the carrier tape 20. The most characteristic constitution of the present invention is the pickup section 60.

The carrier tape 20 includes receiving spaces 22 which are formed to be spaced apart from one another, at a pitch of a regular interval, at a base tape 21 made of a paper material. After small electronic components, such as semiconductor chips, are retained in the receiving spaces 22, the carrier tape 20 is taped by a vinyl cover 23. At one side of the base tape 21, tape transfer holes 24 are formed, at predetermined intervals, in a length direction of the carrier tape 20 wound about a reel. The base tape 21 and the vinyl cover 23 are bonded together at both sides of the retained electronic components, along the length direction of the carrier tape 20. The portion where the tape transfer holes 24 are formed is not taped with the vinyl cover 23. When the width of the carrier tape becomes wide because the size of the retained components is big, the tape transfer holes may be formed at both sides of the carrier tape, along the length direction of the carrier tape.

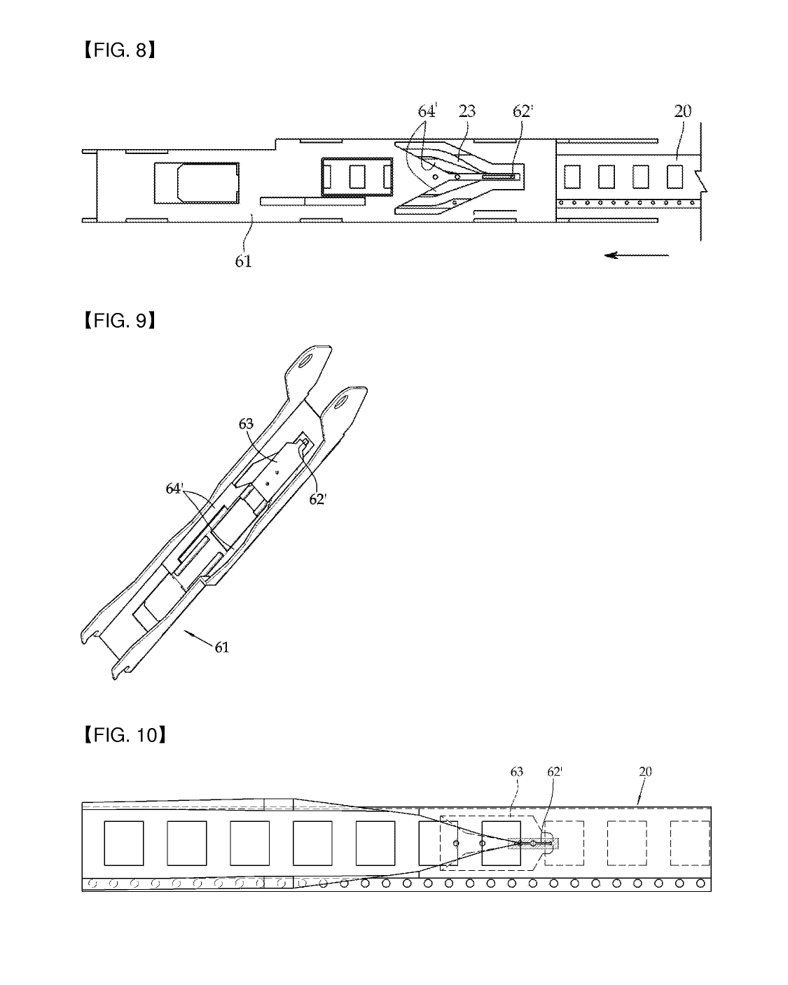

In the carrier tape 20 to be supplied to the tape feeder, a front end of a bonded part where the vinyl cover is bonded to the base tape 21 is diagonally cut, so that the vinyl cover 23 is easily separated from the base tape 21 at the front end of the bonded part. At the front end of the bonded part, the carrier tape 20 is cut in half diagonally across the width direction of the carrier tape 20 as shown in FIG. 7B. Then, at the cut bonded part, a bonding line of the carrier tape remains at only the side opposite to the diagonally cut side. A force of pulling the vinyl cover 23 remains at the bonded part and the force acts as a force of separating the vinyl cover 23 from the base tape 21.

In the above-described tape feeder according to a preferred embodiment of the present invention, the tape storage section 30 and the tape supplying section 40 are installed at the back of the tape feeder body 10, and the pickup section 60 is installed at the front of the tape feeder body 10. The tape guide section 50 is positioned therebetween and guides the carrier tape supplied from the tape supplying section 40 to the pickup section 60.

The tape storage section 30 may be connected to one end of the tape feeder body 10 as illustrated or it may be separately installed at a back of the tape feeder body 10. In accordance with the embodiment of the present invention, the tape storage section 30 is installed at a back end of the tape feeder body 10. The tape storage section 30 comprises: a reel holder 31 in a plate shape, a rotation bar 32, a first reel 34 and a second reel 35. An upper end of the reel holder 31 is connected to the tape feeder body 10 by a rotation shaft 33, so as to be pivotable about the rotation shaft 33. The center of the rotation bar 32 is connected to a lower end of the reel holder 31 by a hinge. The first reel 34 and the second reel 35 are respectively installed at both ends of the rotation bar 32. The reel holder 31 may be installed with only one reel, without installing the rotation bar 32. However, it is preferable to install a plurality of the reels for the work efficiency and the productivity.

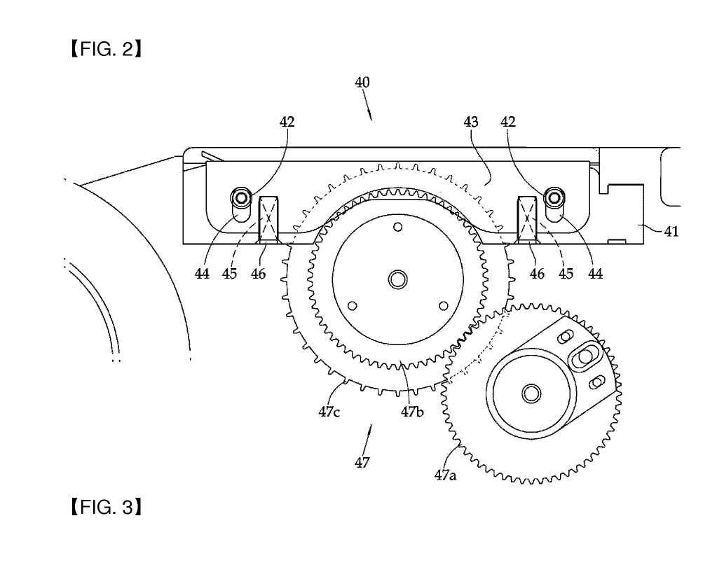

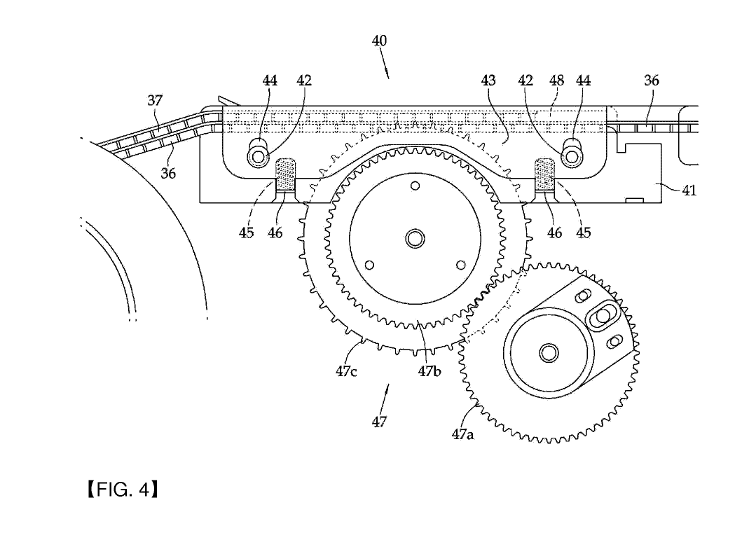

As illustrated in FIGS. 2 and 3, the tape supplying section 40 comprises: a guide member 41 to maintain the position of the carrier tape moving from the tape storage section 30, a guide cover 43 to be connected to the guide member 41, a first driving member 47 to generate a driving force to transfer the carrier tape. The tape supplying section 40 further comprises: guide pins 42 to connect the guide member 41 and the guide cover 43 at a front end and a back end of the tape supplying section 40. A guide groove 44 in the shape of a vertically long opening is formed in the guide cover 43, so that the guide cover 43 is capable of vertically moving by as long as a length of the long opening.

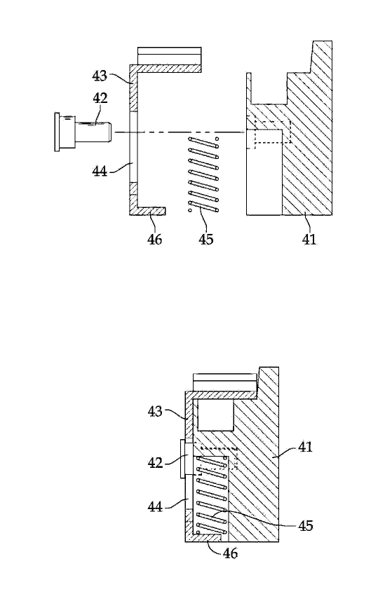

As illustrated in FIG. 4, the guide member 41 includes a receiving space to receive elastic members 45 to be positioned. The elastic members 45 are positioned at a securing part 46 of the guide cover 43. Then, when the guide cover 43 is connected to the guide member 41 by inserting the guide pins 42 into the guide grooves 44, the guide pins 42 are positioned at upper ends of the guide grooves 44 by the elastic force of the elastic members 45 and the weight of the guide cover 43 (refer to FIG. 2). Then, when a first carrier tape 36 is inserted between the guide cover 43 and the guide member 41 and a second carrier tape 37 is inserted on/above the first carrier tape 36, since the guide cover 43 rises upwardly by as much as the thickness of the carrier tape, the guide pins 42 are positioned at lower ends of the guide grooves 44 (refer to FIG. 3). In this manner, when the first carrier tape 36 and the second carrier tape 37 are sequentially stacked between the guide member 41 and the guide cover 43, the first carrier tape 36 is transferred to the pickup section 60 of the tape feeder due to the weight of the guide cover 43 and the elastic force of the elastic members 45. After the first carrier tape 36 is not present, the second carrier tape 37 is automatically moves to the position of the first carrier tape 36 and consecutively supplies the carrier tape to the pickup section 60.

A carrier tape stopper 48 is formed to protrude inside the front end of the guide cover 43. When the carrier tape is pushed to be inserted between the guide cover 43 and the guide member 41, since a front end of the inserted carrier tape comes into contact with the carrier tape stopper 48, the carrier tape is constantly accurately inserted to be mounted onto the tape supplying section 40.

The first driving member 47 to transfer the carrier tape is installed in the tape supplying section 40. The first driving member 47 comprises: a motor (not shown) to generate a driving force, a driving gear 47a to transmit the driving force of the motor, a driven gear 47b to receive the driving force transmitted from the driving gear 47a, and a first sprocket 47c coaxially connected to the driven gear 47b and to transfer the carrier tape. A saw-toothed shape formed around the circumference of the first sprocket 47c engages with the transfer holes 24 formed in the carrier tape, to transfer the carrier tape. The motor may be a step motor or DC motor or it may be suitably selected as occasion demands. The constitution of a group of gears to transmit the driving force of the motor may be varied. When the technical idea of the present invention is used as it is, the driving member may use a cylinder driving method instead of using the motor, or a cam instead of the sprocket. A person skilled in the art may substitute the operation mechanism to transfer the carrier tape with equivalent means, without any technical difficulties.

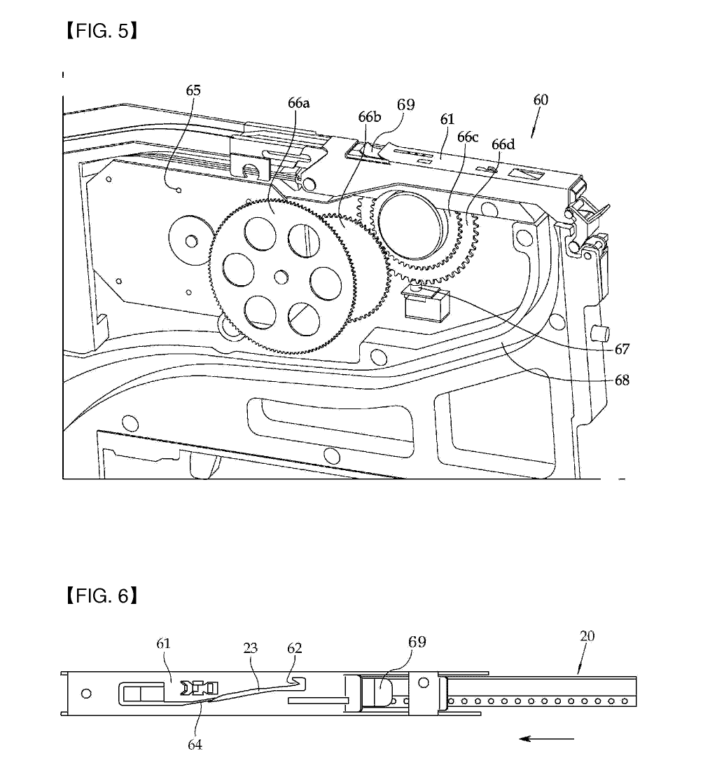

As illustrated in FIG. 5, the pickup section 60 according to a first embodiment of the present invention is installed in the other end of the tape feeder body 10, i.e., at the front of the tape feeder body 10. The pickup section 60 comprises: a tape guide 61 and a second driving member. The tape guide 61 separates the base tape 21 and the vinyl cover 23 of the carrier tape supplied from the tape guide section 50 so that the components retained in the receiving spaces 22 of the base tape 21 can be picked up, and then guides the base tape 21 and the vinyl cover 23 in the same direction simultaneously so that the base tape 21 and the vinyl cover 23 are discharged. The second driving member generates a driving force to transfer the carrier tape. The pickup section 60 further comprises: a tape discharge guide unit 68. After the components retained in the receiving spaces 22 of the base tape 21 are picked up by a nozzle of the chip mounter, the tape discharge guide unit 68 guides the base tape 21 and the vinyl cover 23 to be discharged simultaneously in the same direction. As the base tape 21 and the vinyl cover 23 are discharged in this manner, it is possible to basically solve all problems in that static electricity generates when the separated vinyl cover 23 comes into contact together or gets tangled.

The second driving member comprises: a driving motor 65 to generate a driving force, driving gears 66a and 66b to receive the driving force transmitted from the driving motor 65, a driven gear 66c to receive the driving force transmitted from the driving gears 66a and 66b, and a second sprocket 66d coaxially connected to the driven gear 66c and to transfer the carrier tape. A saw-toothed shape formed around the circumference of the second sprocket 66d engages with the transfer holes 24 formed in the carrier tape, to transfer the carrier tape. The driving motor may be a step motor or DC motor or it may be suitably selected as occasion demands. FIG. 5 illustrates two gears, the driving gears 66a and 66b. However, the constitution of a group of gears to transmit the driving force of the driving motor may be varied. When the technical idea of the present invention is used as it is, the driving member may use a cylinder driving method instead of using the motor, or a cam instead of the sprocket. A person skilled in the art may substitute the operation mechanism to transfer the carrier tape with equivalent means, without any technical difficulties.

After the first driving member 47 installed in the tape supplying section 40 is driven so that the carrier tape is supplied to the pickup section 60, when the second driving member installed in the pickup section 60 starts driving, the first driving member 47 is controlled so as to automatically stop operating.

First sensors 51a and 51b to sense the carrier tape being supplied are attached to the tape supplying section 40. Second sensors 52a and 52b to sense the carrier tape being supplied are attached to suitable positions in the pickup section 60. The first sensors 51a and 51b are installed by two, and the second sensors 52a and 52b are installed by two. Preferably, one of each of the first and second sensors may sense a back end of the first carrier tape 36 which has been supplied, and the other may sense a front end of the second carrier tape 37 which will be supplied. Preferably, a display unit (not shown) may be included to inform the results as sensed by the first and second sensors 51a, 51b, 52a and 52b. The display unit may use any display unit that is capable of visually or auditorily informing the results to an operator.

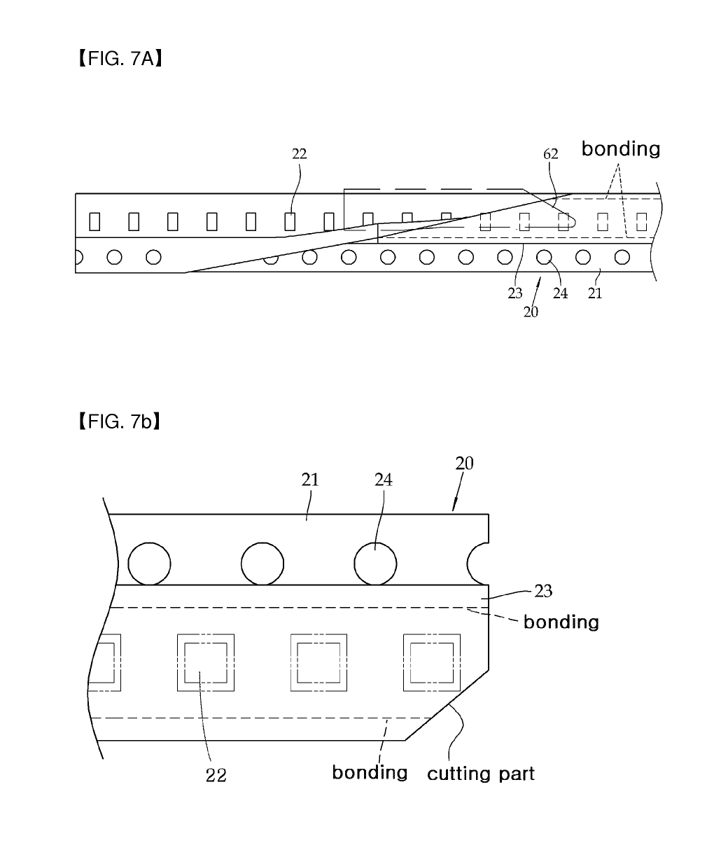

A manner of separating the vinyl cover 23 from the base tape 21 will be described. FIGS. 6 and 7A illustrate the manner of unidirectionally separating the vinyl cover 23 from the base tape 21, along the length direction of the carrier tape 20. A front end of a blade 62 separates a bonded part, along one bonding line formed at one side on the base tape 21 and the vinyl cover 23. Then, the vinyl cover 23 separated from the base tape 21 is inserted into and guided by a vinyl cover guider 64 formed, along the length direction of the tape guide 61. The vinyl cover 23 is transferred by the guide of the vinyl cover guider 64 and is folded at a part of the vinyl cover guider 64, so as to enter inside the tape guide 61. (Since the width of the vinyl cover 23 is fixed, as the carrier tape 20 is transferred, the vinyl cover 23 separately inserted into and guided by the vinyl cover guider 64 is pulled into the tape guide 61 and is automatically folded.) The vinyl cover 23 entering the tape guide 61 is discharged to the tape discharge guide unit 68, together with the base tape 21. Since the bonding condition is maintained in the other bonding line which is formed at the other side on the base tape 21 and the vinyl cover 23 and which is not separated, the base tape 21 and the vinyl cover 23 are discharged together. The vinyl cover guider 64 needs to be formed obliquely not parallel to the length direction on the surface of the tape guide 61 (refer to FIG. 6).

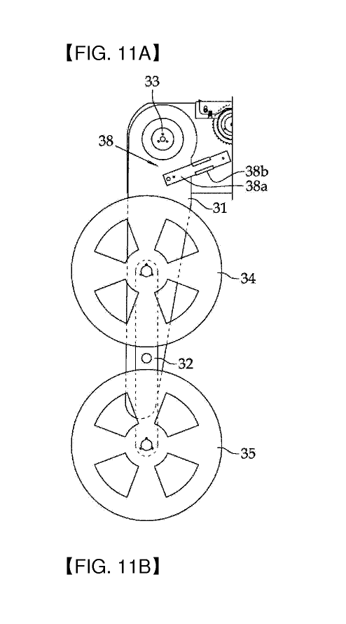

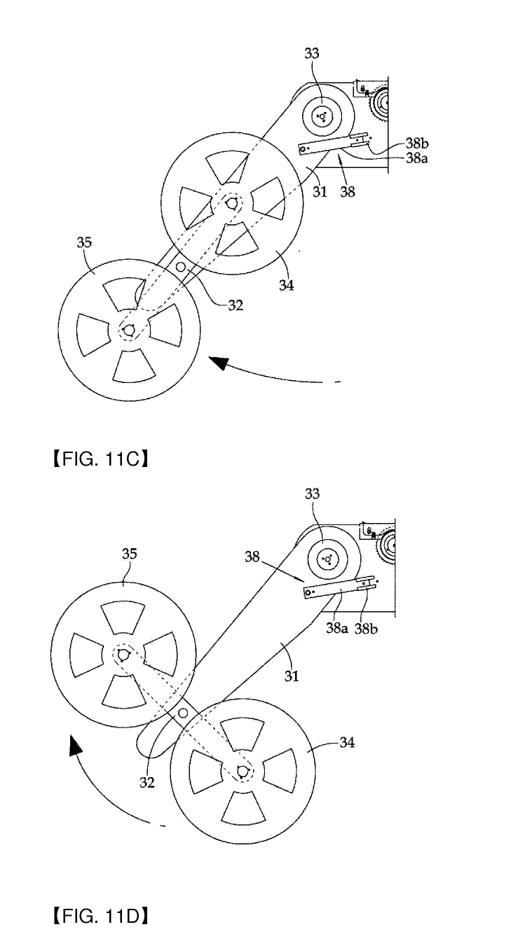

FIGS. 8 and 9 illustrate the manner of bidirectionally separating the vinyl cover 23 from the base tape 21, along the length direction of the carrier tape 20. A front end of a blade 62′ cuts the vinyl cover 23, along a middle line between the bonding lines formed at both sides on the base tape 21 and the vinyl cover 23. Then, the guide unit 63 in a plate shape attached to a bottom of the blade 62′ separates the vinyl cover 23 from the base tape 21. The separated vinyl cover 23 is inserted into and guided by a vinyl cover guider 64′ formed along the length direction of the tape guide 61, so as to be transferred. The vinyl cover 23 being transferred is folded in the same manner as described above. After the components retained in the receiving spaces 22 of the carrier tape 20 are picked up, the base tape 21 and the vinyl cover 23 are together discharged to the tape discharge guide unit 68.

Only when the second sprocket 66d installed in the pickup section 60 accurately operates, the carrier tape 20 can be accurately transferred. Therefore, preferably, a sprocket sensor 67 to sense an accurate rotation of the second sprocket 66d may be attached to a suitable position under or around the second sprocket 66d. Further, it is preferable to include a control (not shown) to immediately correct the driving of the second driving member when any defects in the rotation of the second sprocket 66d are sensed.

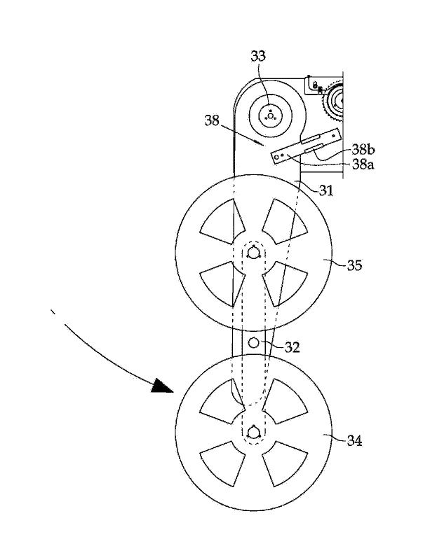

A process of consecutively and automatically supplying the carrier tape will be described with reference to FIGS. 11A through 11E illustrating an example in which two reels are wound. When the first carrier tape 36 wound about the first reel 34 is not present any more, the second carrier tape 37 wound about the second reel 35 is transferred to the pickup section 60 of the tape feeder through the carrier tape supplying section 40. Then, the reel holder 31 rotates around the rotation shaft 33 and the rotation bar 32 clockwise rotates around the hinge connected to the reel holder 31, so that the second reel 35 moves to the original position of the first reel 34 and therefore, the first reel 34 having no carrier tape is replaced by the second reel 35 wound with the new carrier tape, thereby consecutively supplying the carrier tape to the tape supplying section 40.

The reel holder 31 is connected to the tape feeder body 10 so as to be pivotable by the rotation shaft 33. Preferably, a stopper 38 in a bar shape may be installed to restrict the range of pivot of the reel holder 31. The stopper 38 includes a bar 38a and a guide unit 38b. One end of the bar 38a is connected to the reel holder 31 so as to be pivotable, and the other end of the bar 38a is inserted into the guide unit 38b connected to the tape feeder body 10 so as to be pivotable, so that the stopper 38 is structured to slide within the guide unit 38b as the reel holder 31 pivots. Then, the range of pivot of the stopper 38 may be controlled, depending on the length of the bar 38a. In addition to the stopper in the bar shape, any constitution that can limit the range of pivot of the reel holder 31 may be used, without any technical difficulties.

The tape guide 61 separates the vinyl cover from the base tape in the carrier tape being transferred by the carrier tape guide section 50, secures the path of the carrier tape from which the vinyl cover is separated, and guides the base tape and the vinyl cover to the carrier tape discharge guide unit 68. The carrier tape discharge guide unit 68 discharges the base tape and the vinyl cover together in the same direction simultaneously.

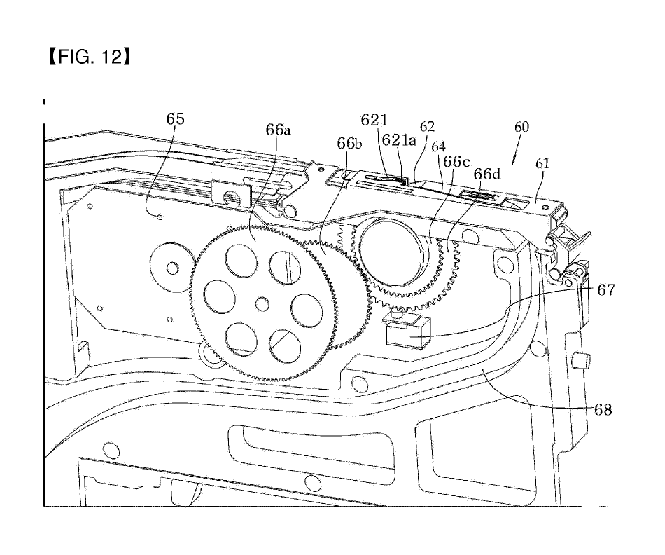

As illustrated in FIG. 12, one end of the tape guide 61 is connected to the tape feeder body by a hinge and the other end thereof is fixed with the tape feeder body by a clamp, so as to be installed. When the clamp is removed as occasion demands, the tape guide 61 pivots around a hinge shaft of the hinge connected to the tape feeder body, by the elastic force using a spring.

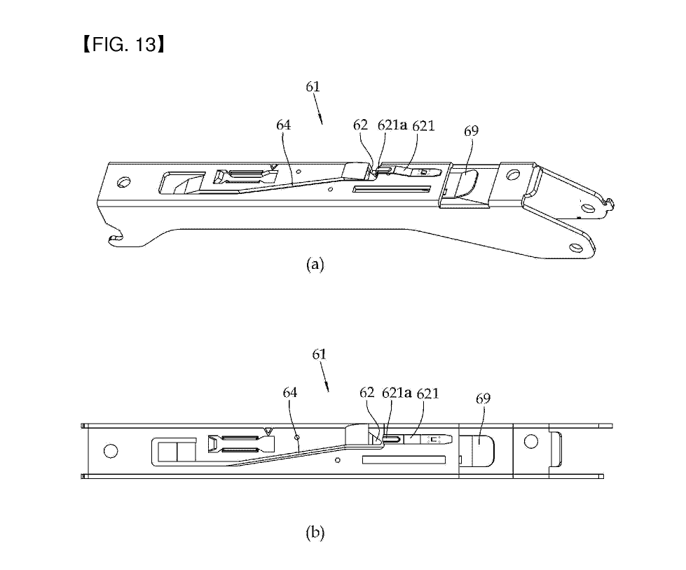

FIG. 13 illustrates a pickup section according to a second embodiment. A tape guide 61 comprises: a blade 62, a hook 621, a vinyl cover guider 64, and a leaf spring 622. The blade 62 separates a vinyl cover from a base tape of a carrier tape being supplied. The hook 621 is positioned in front of the blade 62. A front end of the hook 621 is bent in a ‘┐’ shape. As the carrier tape is caught by the front end of the hook 621, the vinyl cover is easily separated from the base tape at a front end of the carrier tape. The vinyl cover guider 64 guides the vinyl cover separated by the blade 62. The leaf spring 622 is installed to be positioned under the blade 62 and the front end of the hook 621. The leaf spring 622 supports the carrier tape to be in contact with a level plate 69 which is attached to a bottom surface of the tape guide 61.

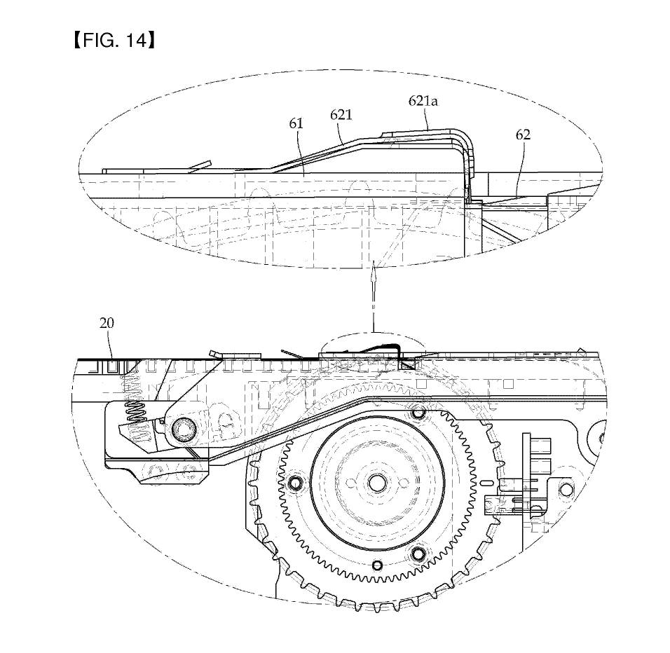

The hook 621 is positioned in front of the blade 62 (i.e., the hook 621 is positioned to be close to a tape guide section rather than the blade). The front end of the hook 621 is in the ‘┐’ shape (refer to FIG. 14.) An outer surface of a bent portion in the front end is locally embossed, to reinforce the rigidity of the hook 621 (i.e., the outer surface of the bent portion is formed to be thicker longitudinally, compared with the other portions as illustrated in FIG. 14). Or a reinforcement plate 621a is further attached to the outer surface of the bent portion in the front end of the hook. The horizontal portion of the hook 621 is attached and fixed to the top of the tape guide 61 by welding or the like. The method of attaching and fixing the horizontal portion of the hook 621 to the top of the tape guide 61 may vary.

The leaf spring 622 pushes upwardly the carrier tape 20 to be in contact with the level plate 69 under the tape guide 61. Even if the carrier tape 20 is transferred in a bent state, the leaf spring 622 restores the carrier tape to a normal shape. A top of the leaf spring 622 is in the shape of a plate. The leaf spring 622 comprises: a supporting member 622a, a block 622b and a protrusion 622c. The supporting member 622a to support the leaf spring 622 is positioned under the plate. Preferably, the supporting member 622a may be made of an elastic material, such as rubber sponge. The block 622b secures a bottom of the supporting member 622a and both ends of the leaf spring 622 and is made of poly acetyl (POM). Preferably, the protrusion 622c is formed under the block 622b. The protrusion 622c makes it easy to fix the leaf spring 622 on the top of the tape feeder body 10. Accordingly, an opening to receive the protrusion 622c needs to be formed on the top of the tape feeder body. The leaf spring may be fixed onto the top of the tape feeder body in any other method that is capable of fixing the leaf spring onto the tape feeder body. Further, the supporting member 622a and the block 622b may be formed in a single body.

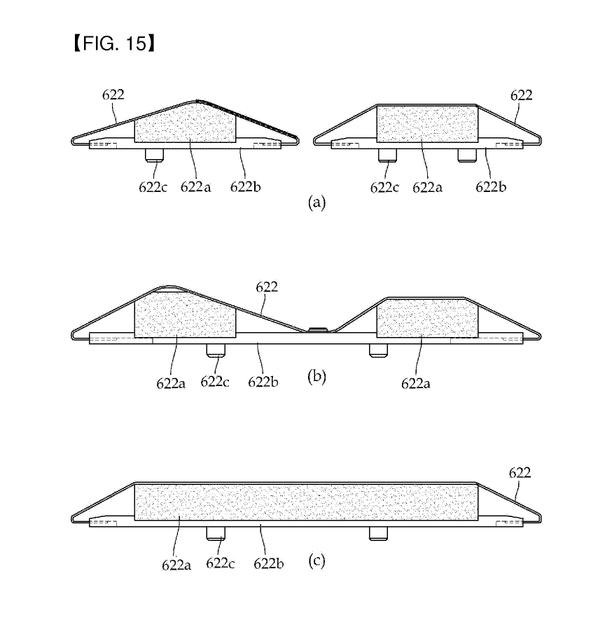

As illustrated in FIG. 15, the leaf spring 622 may be formed in various shapes. The entire top of the leaf spring 622 may be formed in a single plate shape (FIG. 15 (c)), or two leaf springs (i.e., one with a convex top part and the other with a flat top part) may be separately installed (FIG. 15 (a)), or one leaf spring connecting a convex top part and a flat top part may be installed (FIG. 15(b)). The leaf spring including the convex top part needs to be installed such that the convex top part is positioned between the blade 62 and the front end of the hook 621.

The operation of separating the vinyl cover 23 from the base tape 21 will be described. As the front end of the carrier tape 20 being transferred by the tape guide section 50 is caught by the bent front end of the hook 621, the vinyl cover 23 is separated from the base tape. Then, the front end of the blade 62 enters into the space formed when the vinyl cover 23 is separated from the base tape 21, separates the bonded part, along one bonding line formed at one side of the base tape 21 and vinyl cover 23. Then, the separated vinyl cover 23 is inserted into and guided and transferred by the vinyl cover guider 64 formed along the length direction of the tape guide 61. The vinyl cover 23 being transferred is folded at a part of the vinyl cover guider 64 and enters inside the tape guide 61. (Since the width of the vinyl cover 23 is fixed, as the carrier tape 20 is transferred, the vinyl cover 23 separately inserted into and guided by the vinyl cover guider 64 is pulled into the tape guide 61 and is automatically folded.) The vinyl cover 23 entering the tape guide 61 is discharged to the tape discharge guide unit 68, together with the base tape 21. Since the bonding condition is maintained in the other bonding line which is formed at the other side of the base tape 21 and the vinyl cover 23 and which is not separated, the base tape 21 and the vinyl cover 23 are discharged together. The vinyl cover guider 64 needs to be formed obliquely not parallel to the length direction on the surface of the tape guide 61 (refer to FIG. 13(a) and FIG. 13(b)).

If the carrier tape is transferred in a deformed state, i.e., not in a flat, straight level state (e.g., in a state where the base tape of the carrier tape is bent toward the receiving spaces, along the length direction of the tape), the leaf spring 622 supports the carrier tape so as to keep the tape in a normal state where the carrier tape is flat and straight. The tape feeder is then capable of continuously consistently supplying the components to the chip mounter.

As described above, in the carrier tape feeder for a chip mounter according to the present invention, after the vinyl cover is separated from the base tape of the carrier tape and the components retained in the carrier tape are picked up, the base tape and the vinyl cover are discharged together in the same direction simultaneously, thereby basically solving the problem caused when the vinyl cover being discharged gets tangled or comes into contact together. Therefore, since the base tape and the vinyl cover are smoothly discharged, the components are accurately fed to the chip mounter. This is capable of significantly reducing a rate of producing defective products.

Further, even if the base tape of the carrier tape is transferred in an abnormally deformed state, i.e., even if the base tape is transferred in a bent or curved state, not in a straight level state in the length direction, since the leaf spring supports the carrier tape so as to be restored from the deformed state to the normal state, the electronic components retained in the receiving spaces of the carrier tape are normally, consecutively and automatically fed to the chip mounter. Furthermore, since the front end of the carrier tape is caught by the hook, the vinyl cover affixed to the base tape is easily separated from the base tape.

The invention has been described using preferred exemplary embodiments. However, it is to be understood that the scope of the invention is not limited to the disclosed embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

What is claimed is:

1. A carrier tape feeder for a chip mounter which consecutively and automatically supplies components retained in a carrier tape to the chip mounter, comprising:
a pickup section to separate a part of a vinyl cover from a base tape of the carrier tape so that the components retained in the base tape can be picked up,
wherein the pickup section connected to an end of a tape feeder body comprises:
a tape guide to secure a path of the carrier tape from which the part of the vinyl cover is separated longitudinally and to discharge the base tape and the vinyl cover together in the same direction simultaneously,
wherein the tape guide comprises:
a blade to separate longitudinally the vinyl cover from the base tape of the carrier tape being fed; and
a vinyl cover guider to guide the separated vinyl cover.

2. The carrier tape feeder according to claim 1, wherein the tape guide comprises:
a blade to cut longitudinally a middle part of the vinyl cover from the base tape of the carrier tape being supplied;
a guide unit installed under the blade, to separate the vinyl cover from the base tape; and
a vinyl cover guider to guide the separated vinyl cover.

3. The carrier tape feeder according to claim 1 or claim 2, further comprising:
a tape supplying section to supply the carrier tape transferred from a reel wound with the carrier tape to the pickup section,
wherein the tape supplying section comprises:
a guide member positioned at an upper position of the tape supplying section, to secure and pass the carrier tape supplied from a tape storage section;
a guide cover to be connected with the guide member; and
a first driving member to generate a driving force to transfer the carrier tape.

4. The carrier tape feeder according to claim 3. wherein the tape supplying section further comprises:
guide pins to be positioned at both sides of a front end and a back end of the tape supplying section and to connect the guide member and the guide cover.

5. The carrier tape feeder according to claim 4, wherein the tape supplying section further comprises:
guide grooves formed at the guide cover, each having a shape of a long opening being long in a vertical direction in which the guide pin is inserted.

6. The carrier tape feeder according to claim 5, wherein the tape supplying section further comprises:
an elastic member to elastically support the guide cover to the guide member.

7. The carrier tape feeder according to claim 3, wherein the tape supplying section further comprises:
a carrier tape stopper formed so as to protrude inside the front end of the guide cover.

8. The carrier tape feeder according to claim 3, wherein the tape supplying section further comprises:
a first sensor to sense the carrier tape being supplied.

9. The carrier tape feeder according to claim 3, wherein the pickup section further comprises:
a second sensor to sense the carrier tape.

10. The carrier tape feeder according to claim 3, wherein the first driving member comprises:
a motor to generate the driving force;
a driving gear to receive the transmitted driving force from the motor;
a driven gear to receive the transmitted driving force form the driving motor; and
a first sprocket coaxially connected with the driven gear, to transfer the carrier tape.

11. The carrier tape feeder according to claim 1 or 2, wherein the pickup section further comprises:
a second driving member to generate the driving force to transfer the carrier tape,
wherein the second driving member comprises:
a motor to generate the driving force;
a driving gear to receive the transmitted driving force from the motor;
a driven gear to receive the transmitted driving force form the driving motor; and
a second sprocket coaxially connected with the driven gear, to transfer the carrier tape.

12. The carrier tape feeder according to claim 1 or 2, wherein the pickup section further comprises:
a tape discharge guide unit to guide the base tape and the vinyl cover to be discharged after the components retained in the base tape are picked up.

13. The carrier tape feeder according to claim 1 or claim 2, wherein the tape guide comprises:
a blade to separate the vinyl cover from the base tape of the supplied carrier tape;
a hook with a front end bent in a ‘┐’ shape to catch a front end of the carrier tape so that the vinyl cover is easily separated from the base tape;
a leaf spring to be installed to be positioned under the blade and the front end of the hook and to support the carrier tape; and
a vinyl cover guider to guide the vinyl cover separated by the blade.

14. The carrier tape feeder according to claim 13, wherein the hook further comprises:
a local embossing or a reinforcement plate attached to an outer surface of its bent portion, to reinforce the rigidity of the hook.

15. The carrier tape feeder according to claim 13, wherein the leaf spring comprises:
a top in the shape of a plate;
a supporting member positioned under the plate, to support the leaf spring;
a block to secure a bottom of the supporting member and both ends of the leaf spring; and
a protrusion formed under the block.

16. The carrier tape feeder according to claim 1 or claim 2, wherein the carrier tape comprises:
a front end of a bonded part where the vinyl cover is bonded to the base tape is cut diagonally.
